(19) United States
(12) Patent Application Publication
(10) Pub. No.: US 2026/0094648 A1
(43) Pub. Date: Apr. 2, 2026

(54) ERASE OPERATION FOR NON-VOLATILE MEMORY CELL

(71) Applicant: Silicon Storage Technology, Inc., San Jose, CA (US)

(72) Inventors: Anh Ly, San Jose, CA (US); Hien Pham, Ho Chi Minh (VN); Kyle McMartin, Mountain View, CA (US); Kha Nguyen, Ho Chi Minh (VN); Jeng-Wei Yang, Zhubei City (TW); Jong-Won Yoo, Morgan Hill, CA (US); Man-Tang Wu, Hsinchu County (TW); Yen Jung Shen, Tainan (TW); Thoan Nguyen, Dong Nai (VN); Nghia Nguyen, Ho Chi Minh (VN); Viet Nguyen, Ho Chi Minh (VN); Hieu Van Tran, San Jose, CA (US); Xiaozhou Qian, Shanghai (CN)

(21) Appl. No.: 19/027,563

(22) Filed: Jan. 17, 2025

(30) Foreign Application Priority Data
Sep. 27, 2024 (CN) 202411364243.3

(51) Int. Cl. G11C 16/14; G11C 16/34

(52) U.S. Cl. CPC G11C 16/14; G11C 16/3445

(57) ABSTRACT

In one example, a method for erasing a non-volatile memory cell comprises performing a pre-erase sequence comprising applying voltages in a step pattern to a terminal of the non-volatile memory cell; and performing an erase sequence comprising applying a plurality of pulses of increasing voltages to the terminal of the non-volatile memory cell.

### RELATED APPLICATION

This application claims the benefit of Chinese Patent Application No. 202411364243.3, filed on Sep. 27, 2024.

### FIELD OF THE INVENTION

An improved system and method for an erase operation for a non-volatile memory cell are disclosed.

### BACKGROUND OF THE INVENTION

Non-volatile memories are well known. For example, U.S. Pat. No. 5,029,130 (“the '130 patent”), which is incorporated herein by reference, discloses an array of split gate non-volatile memory cells, which are a type of flash memory cells. Such a memory cell 110 is shown in FIG. 1. Each memory cell 110 includes source region 14 and drain region 16 formed in semiconductor substrate 12, with channel region 18 there between. Floating gate 20 is formed over and insulated from (and controls the conductivity of) a first portion of the channel region 18, and over a portion of the source region 14. Word line terminal 22 (which is typically coupled to a word line) has a first portion that is disposed over and insulated from (and controls the conductivity of) a second portion of the channel region 18, and a second portion that extends up and over the floating gate 20. The floating gate 20 and word line terminal 22 are insulated from the substrate 12 by a gate oxide. Bitline 24 is coupled to drain region 16.

Memory cell 110 is erased (where electrons are removed from the floating gate) by placing a high positive voltage on the word line terminal 22, which causes electrons on the floating gate 20 to tunnel through the intermediate insulation from the floating gate 20 to the word line terminal 22 via Fowler-Nordheim (FN) tunneling.

Memory cell 110 is programmed by source side injection (SSI) with hot electrons (where electrons are placed on the floating gate) by placing a positive voltage on the word line terminal 22, and a positive voltage on the source region 14. Electron current will flow from the drain region 16 towards the source region 14. The electrons will accelerate and become heated when they reach the gap between the word line terminal 22 and the floating gate 20. Some of the heated electrons will be injected through the gate oxide onto the floating gate 20 due to the attractive electrostatic force from the floating gate 20.

Memory cell 110 is read by placing positive read voltages on the drain region 16 and word line terminal 22 (which turns on the portion of the channel region 18 under the word line terminal). If the floating gate 20 is positively charged (i.e., erased of electrons), then the portion of the channel region 18 under the floating gate 20 is turned on as well, and current will flow across the channel region 18, which is sensed as the erased or “1” state. If the floating gate 20 is negatively charged (i.e., programmed with electrons), then the portion of the channel region under the floating gate 20 is mostly or entirely turned off, and current will not flow (or there will be little flow) across the channel region 18, which is sensed as the programmed or “0” state.

Table No. 1 depicts typical voltage and current ranges that can be applied to the terminals of memory cell 110 for performing read, erase, and program operations:

TABLE NO 1
Operation of Flash Memory Cell 110 of FIG. 1

| | WL | BL | SL |
|---|---|---|---|
| Read | 2-3 V | 0.6-2 V | 0 V |
| Erase | ~11-13 V | 0 V | 0 V |
| Program | 1-2 V | 10.5-3 μA | 9-10 V |

Other split gate memory cell configurations, which are other types of flash memory cells, are known. For example, FIG. 2 depicts a four-gate memory cell 210 comprising source region 14, drain region 16, floating gate 20 over a first portion of channel region 18, a select gate 22 (typically coupled to a word line, WL) over a second portion of the channel region 18, a control gate 28 over the floating gate 20, and an erase gate 30 over the source region 14. This configuration is described in U.S. Pat. No. 6,747,310, which is incorporated herein by reference for all purposes. Here, all gates are non-floating gates except floating gate 20, meaning that they are electrically connected or connectable to a voltage source. Programming is performed by heated electrons from the channel region 18 injecting themselves onto the floating gate 20. Erasing is performed by electrons tunneling from the floating gate 20 to the erase gate 30.

Table No. 2 depicts typical voltage and current ranges that can be applied to the terminals of memory cell 210 for performing read, erase, and program operations:

TABLE NO 2
Operation of Flash Memory Cell 210 of FIG. 2

| | WL/SG | BL | CG | EG | SL |
|---|---|---|---|---|---|
| Read | 1.0-2 V | 0.6-2 V | 0-2.6 V | 0-2.6 V | 0 V |
| Erase | −0.5 V/0 V | 0 V | 0 V/−8 V | 8-12 V | 0 V |
| Program | 1 V | 0.1-1 μA | 8-11 V | 4.5-9 V | 4.5-5 V |

FIG. 3 depicts a three-gate memory cell 310, which is another type of flash memory cell. Memory cell 310 is identical to the memory cell 210 of FIG. 2 except that memory cell 310 does not have a separate control gate. The erase operation (whereby erasing occurs through use of the erase gate) and read operation are similar to that of the FIG. 2 except there is no control gate bias applied. The programming operation also is done without the control gate bias, and as a result, a higher voltage is applied on the source line during a program operation to compensate for a lack of control gate bias.

Table No. 3 depicts typical voltage and current ranges that can be applied to the terminals of memory cell 310 for performing read, erase, and program operations:

TABLE NO 3
Operation of Flash Memory Cell 310 of FIG. 3

| | WL/SG | BL | EG | SL |
|---|---|---|---|---|
| Read | 0.7-2.2 V | 0.6-2 V | 0-2.6 V | 0 V |
| Erase | −0.5 V/0 V | 0 V | 11.5 V | 0 V |
| Program | 1 V | 0.2-3 μA | 4.5 V | 7-9 V |

FIG. 4 depicts stacked gate memory cell 410, which is another type of flash memory cell. Memory cell 410 is similar to memory cell 110 of FIG. 1, except that floating gate 20 extends over the entire channel region 18, and control gate 22 (which here will be coupled to a word line) extends over floating gate 20, separated by an insulating layer (not shown). The erase is done by FN tunneling of electrons from FG to substrate, programming is by channel hot electron (CHE) injection at region between the channel 18 and the drain region 16, by the electrons flowing from the source region 14 towards to drain region 16 and read operation which is similar to that for memory cell 210 with a higher control gate voltage.

Table No. 4 depicts typical voltage ranges that can be applied to the terminals of memory cell 410 and substrate 12 for performing read, erase, and program operations:

TABLE NO 4
Operation of Flash Memory Cell 410 of FIG. 4

| | CG | BL | SL | Substrate |
|---|---|---|---|---|
| Read | 2-5 V | 0.6-2 V | 0 V | 0 V |
| Erase | −8 to − 10 V/0 V | FLT | FLT | 8-10 V/15-20 V |
| Program | 8-12 V | 3-5 V | 0 V | 0 V |

The methods and means described herein may apply to other non-volatile memory technologies such as FINFET split gate flash or stack gate flash memory, NAND flash, SONOS (silicon-oxide-nitride-oxide-silicon, charge trap in nitride), MONOS (metal-oxide-nitride-oxide-silicon, metal charge trap in nitride), ReRAM (resistive ram), PCM (phase change memory), MRAM (magnetic ram), FeRAM (ferroelectric ram), CT (charge trap) memory, CN (carbon-tube) memory, OTP (bi-level or multi-level one time programmable), and CeRAM (correlated electron ram), without limitation.

During erase operations, high voltages such as those indicates in Table Nos. 1, 2, 3, and 4, above, are applied to word line terminal 22 of memory cell 110 in FIG. 1, erase gate terminal 30 of memory cell 210 in FIG. 2, erase gate terminal 30 of memory cell 310 in FIG. 3, and control gate terminal 22 of memory cell 410 in FIG. 4, respectively, depending on the type of memory cell that is used. Due to the voltage difference between these terminals and other portions of the memory cell, there is significant stress placed on the memory cell, and over time the memory cell will degrade after a substantial number of erase operations have occurred such that the cell becomes unusable. Existing systems often degrade after 10,000 erase cycles.

What is needed is an improved system and method for performing erase operations to increase the longevity of memory cells to enable them to perform a greater number of erase cycles before degradation occurs.

### SUMMARY OF THE INVENTION

An improved system and method for an erase operation for a non-volatile memory cell are disclosed.

### BRIEF DESCRIPTION OF THE DRAWINGS

FIG. 1 depicts a prior art split gate flash memory cell.

FIG. 2 depicts another prior art split gate flash memory cell.

FIG. 3 depicts another prior art split gate flash memory cell.

FIG. 4 depicts another prior art split gate flash memory cell.

FIG. 5 depicts a memory system.

FIG. 6 depicts an erase waveform.

FIG. 7 depicts an erase method.

FIG. 8 depicts an erase waveform.

FIG. 9 depicts an erase waveform.

FIG. 10 depicts an erase waveform.

FIG. 11 depicts a state machine and a counter.

### DETAILED DESCRIPTION OF THE INVENTION

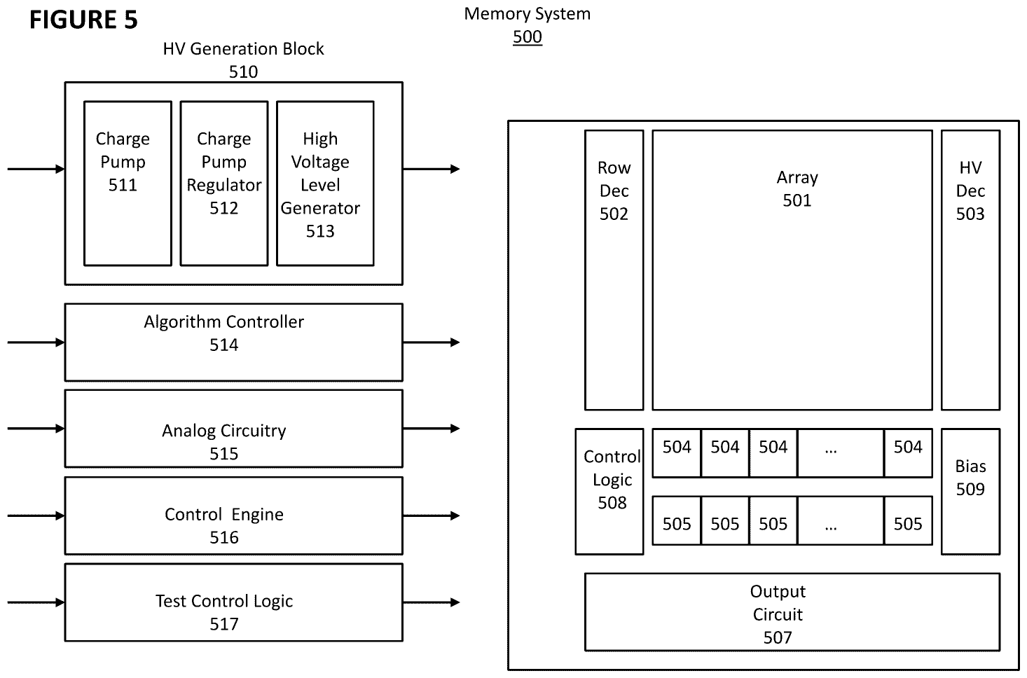

FIG. 5 depicts a block diagram of memory system 500. Memory system 500 comprises array 501, row decoder 502, high voltage decoder 503, column decoders 504, bit line drivers 505, output circuit 507, control logic 508, and bias generator 509. Memory system 500 further comprises high voltage generation block 510, which comprises charge pump 511, charge pump regulator 512, and high voltage level generator 513. Memory system 500 further comprises algorithm controller 514 (which can perform algorithms for programming, erasing), analog circuitry 515, control engine 516 (which can perform functions such as erase, program, read, and test and can comprise embedded microcontroller logic), and test control logic 517.

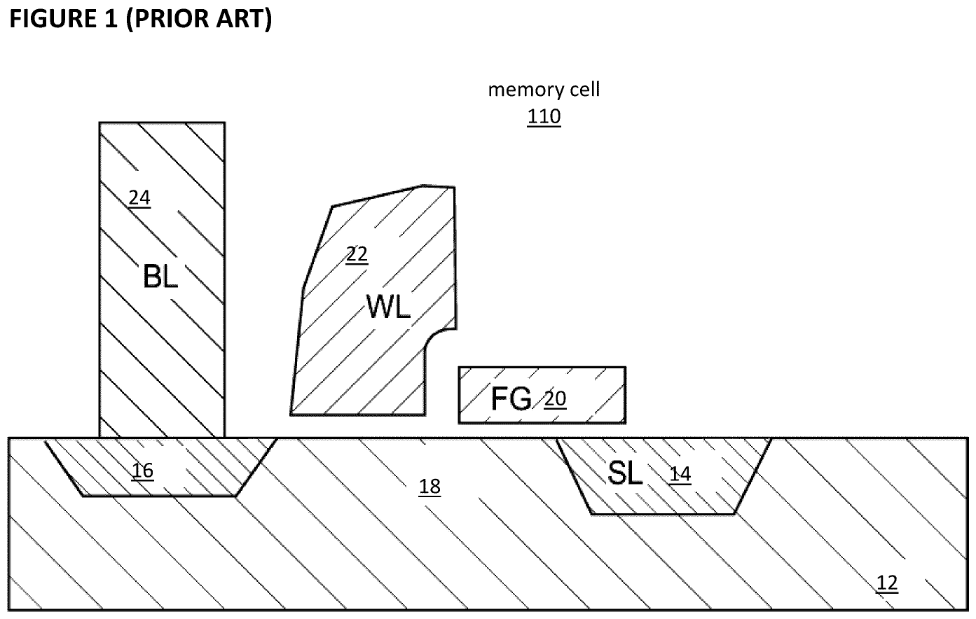

Array 501 comprises rows and columns of non-volatile memory cells, such as memory cells 110, 210, 310, or 410 from FIGS. 1-4, respectively.

Output circuit 507 may include sense amplifiers that are used to convert output data from array 501 into binary digital bits.

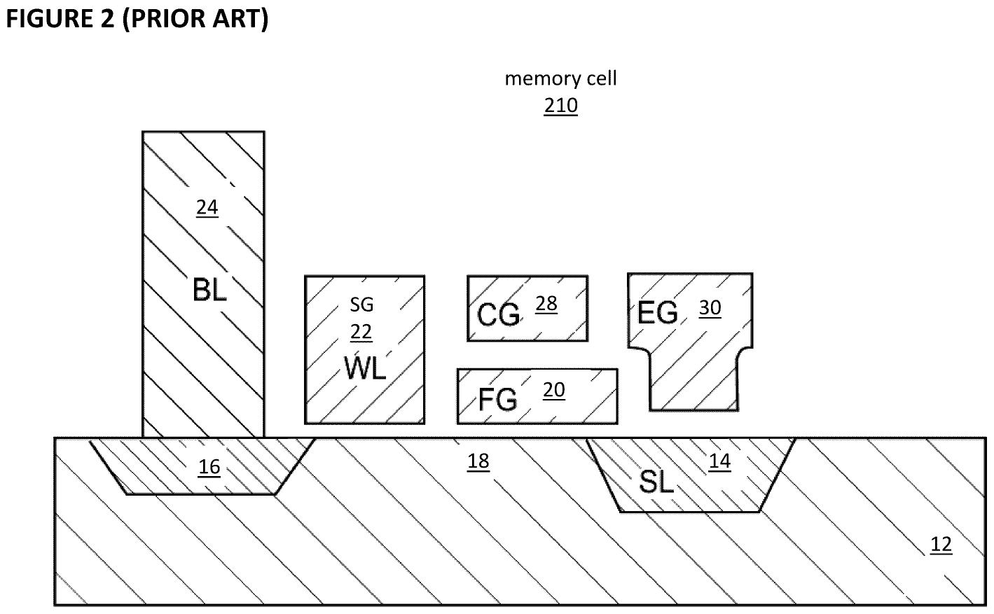

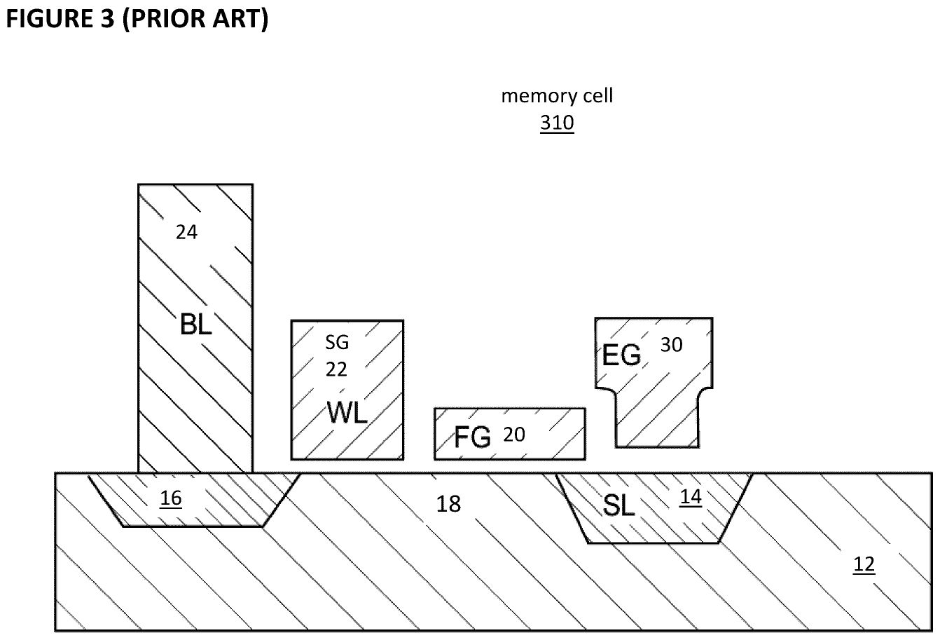

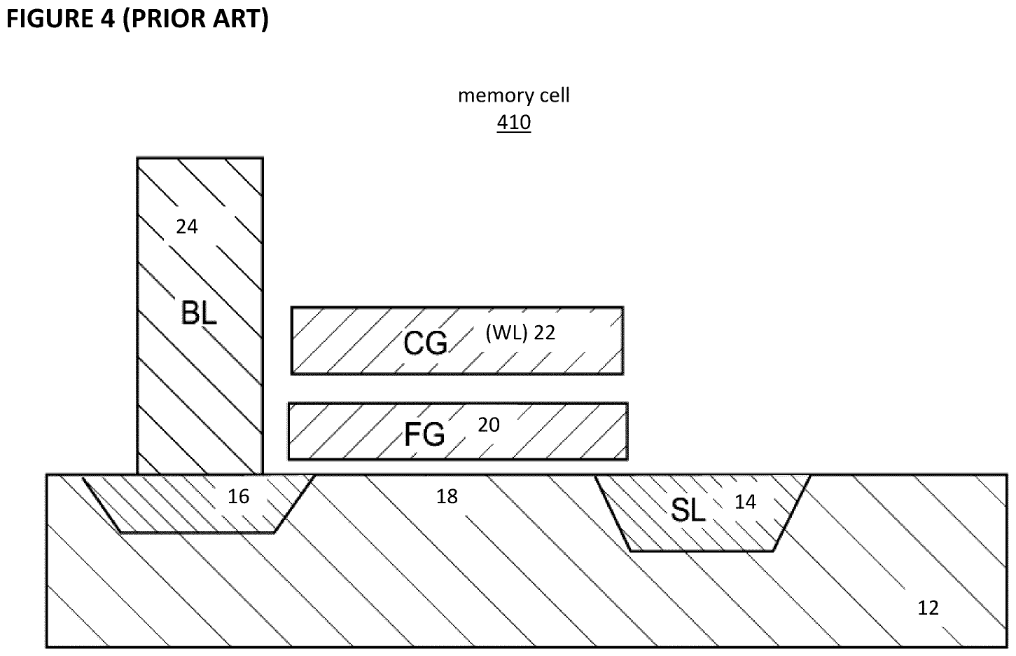

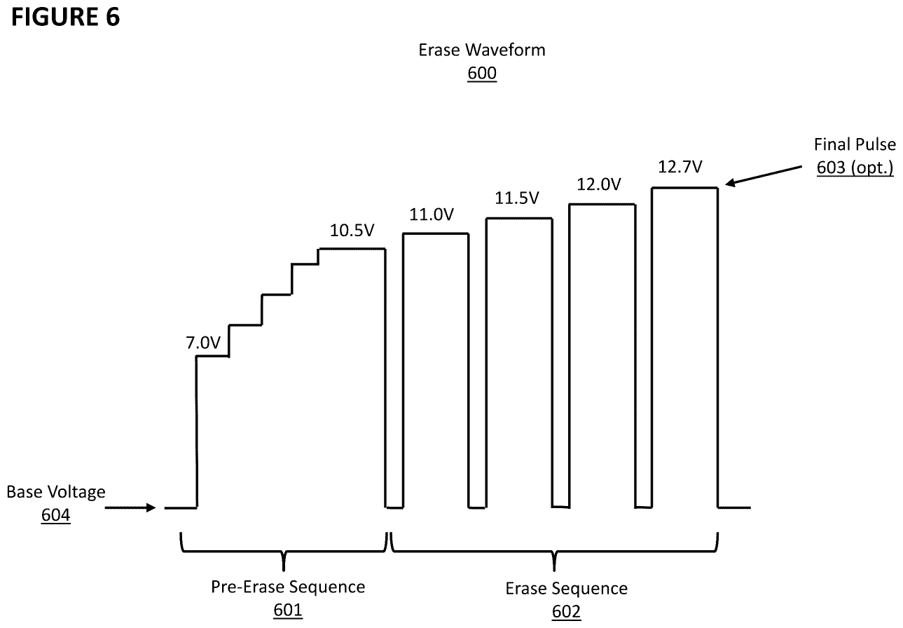

FIG. 6 depicts erase waveform 600. Erase waveform 600 is an example of a voltage waveform to be applied to word line terminal 22 of memory cell 110 in FIG. 1, erase gate terminal 30 or control gate terminal 28 of memory cell 210 in FIG. 2, erase gate terminal 30 of memory cell 310 in FIG. 3, and control gate terminal 22 or substrate 18 of memory cell 410 in FIG. 4 during an erase operation. Erase waveform 600 is generated by high voltage generation block 510 and algorithm controller 514.

Erase waveform 600 comprises pre-erase sequence 601 and erase sequence 602.

Pre-erase sequence 601 comprises a sequence of voltages that increase over time in a step pattern. In this example, the initial voltage is 7.0V and the final voltage is 10.5V, and each step is an increment of 1.0V with a duration of 0.1-0.5 ms. Alternatively, the steps can have a variable magnitude (e.g., the steps increase or decrease in size as the sequence progresses) or variable duration (e.g., the duration of each step increases or decreases in size as the sequence progresses).

After pre-erase sequence 601 is performed, the voltage drops to base level 604, which can be ground or another intermediate voltage, for a duration that in this example is shorter than the duration of pre-erase sequence 601 and of each pulse in erase sequence 602.

The initial voltage, the final voltage, the number of steps, the duration of each step, and the increase between steps in pre-erase sequence are parameters that can be provided, during a programing process or a configuration process, to algorithm controller 514, which in turn generates pre-erase sequence 601 in conjunction with high voltage generation block 510.

Erase sequence 602 comprises a sequence of pulses that increase over time in a step pattern. In this example, the initial pulse is 11.0V, and the next-to-final pulse is 12.0V, and each step is an increment of 0.5V with a duration of 0.1-1 ms. The size of the voltage increments between consecutive pulses can be the same or can be different. That is, the increments can be the same size, the increment size can increase with each subsequent pulse, or the increment size can decrease with each subsequent pulse. Optionally, erase sequence 602 comprises final pulse 603 that is larger in voltage than the next-to-final pulse by an amount that is greater than the previous increments between pulses in erase sequence 602. Alternatively, the voltage of final pulse 603 can be slightly smaller or equal to the next-to-final pulse. In this example, the final pulse is 12.7V with a duration of 0.1-1 ms. Final pulse 603 ensures that the erase operation has been effective by increasing the margin of the erase cells.

After each pulse, erase waveform 600 returns to base level 604 and a verify operation can be performed. If the verify operation indicates that the erase operation has been effective, erase waveform 600 can terminate and the erase operation is concluded.

Alternatively, the pulses of erase sequence 602 can be generated by a ramp control algorithm that ramps up the pulses and ramps down the pulses to reduce unwanted effects such as high voltage breakdown degradation of the HV enabling or disabling circuitry or other effects.

The voltages and pulse-widths of each pulse in erase sequence 602, including final pulse 603, are parameters that can be provided or configured, during a programing process or a configuration process, to algorithm controller 514, which in turn generates erase sequence 602 in conjunction with high voltage generation block 510.

Pre-erase sequence 601 and erase sequence 602 reduce the amount of stress on the memory cell compared to a situation where a constant high erase voltage is applied to the cell from the outset.

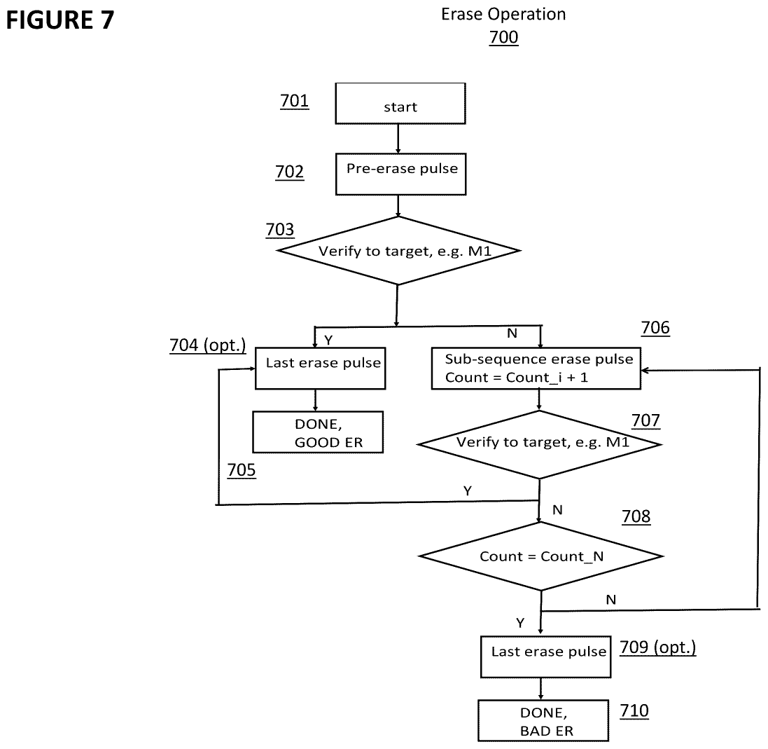

FIG. 7 depicts erase operation 700, which is a method of applying erase waveform 600 in FIG. 6. Erase operation 700 begins (701). Pre-erase sequence 601 is performed (702). A verification is performed, where a read operation is performed on the cell by applying voltages to terminals of the cells according to Tables Nos. 1-4, above, and a current drawn by the cell is measured and compared against a target current (703). If the verification is positive (meaning the measured current equals or exceeds the target value), optionally a final pulse 603 is applied (704), and then erase operation 700 is complete (705). If verification is negative (meaning the measured current is less than the target value), erase sequence 602 is performed, and a counter is reset to hold the count value “0” (706).

A verification is performed (707). If verification is positive, optionally final pulse 603 is applied (704), and then erase operation 700 is complete (705). If verification is negative, then the counter value is compared against a maximum value, Count_N (708); if the values do not match, the process returns to operation 706 and the counter increments; if the values do match, then a final pulse optionally is applied (709), and erase operation 700 is complete and the cell is designated as bad (710). Optionally, a bad cell can be replaced with a replacement cell going forward, for example, by replacing the row of the bad cell with a redundant row or the column of the bad cell with a redundant column.

Alternatively, operation 703 (verify operation) after pre-erase sequence 702 can be skipped or eliminated.

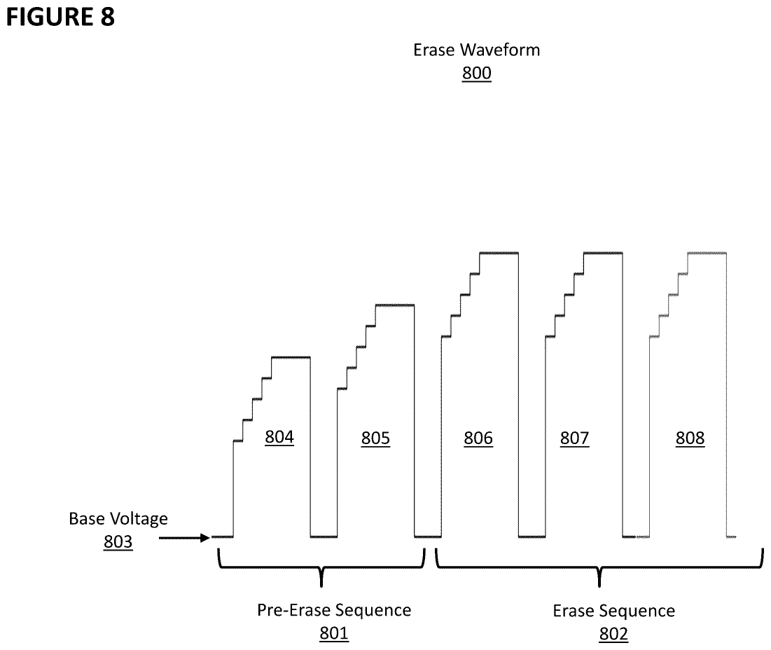

FIG. 8 depicts erase waveform 800. Erase waveform 800 is an example of a voltage waveform to be applied to word line terminal 22 of memory cell 110 in FIG. 1, erase gate terminal 30 or control gate terminal 28 of memory cell 210 in FIG. 2, erase gate terminal 30 of memory cell 310 in FIG. 3, and control gate terminal 22 or substrate 18 of memory cell 410 in FIG. 4 during an erase operation. Erase waveform 800 is generated by high voltage generation block 510 and algorithm controller 514.

Erase waveform 800 comprises pre-erase sequence 801 and erase sequence 802.

In this example, pre-erase sequence 801 may comprise a plurality of pre-erase pulses such as sequence (aka pulse) 804 and sequence 805. Sequence 804 comprises varying voltages in a step pattern, where the voltage increases in a step pattern or decreases in a step pattern. The duration of each step can be uniform or can increase or decrease as the sequence progresses. Sequence 805 also comprises varying voltages in a step pattern, where the voltage increases in a step pattern or decreases in a step pattern, and in this example has a larger starting voltage and a larger ending voltage than sequence 804. The duration of each step can be uniform or can increase or decrease as the sequence progresses. Alternatively, the starting voltage for all pulses in pre-erase sequence 801 can be the same. After each of sequences 804 and 805, the voltage drops to base level 803, which can be ground or an intermediate voltage, for a short duration.

The initial voltage, the final voltage, the number of steps, the duration of each step (for example, each pulse can have the same duration of value T, or the duration of the pulses can increase or decrease as the sequence progresses), the increase between steps in each sequence 804 and 805, and the number of sequences are parameters that can be provided or configured, during a programing process or a configuration process, to algorithm controller 514, which in turn generate pre-erase sequence 801 in conjunction with high voltage generation block 510.

In this example, erase sequence 802 comprises sequence 806, sequence 807, and sequence 808. Sequences 806, 807, and 808 each comprises increasing voltages in a step pattern with the same starting voltage and the same ending voltage. After each of sequences 806, 807, and 808, the voltage drops to base level 803, which can be ground or another voltage, for a short duration.

The initial voltage, the final voltage, the number of steps, the duration of each step, the increase between steps in each sequence 806, 807, and 808, and the number of sequences are parameters that can be provided, during a programing process or a configuration process, to algorithm controller 514, which in turn generates erase sequence 802 in conjunction with high voltage generation block 510.

Pre-erase sequence 801 and erase sequence 802 reduce the amount of stress on the memory cell compared to a situation where a constant high erase voltage is applied to the cell from the outset.

Erase operation 700 in FIG. 7 can be performed using erase waveform 800.

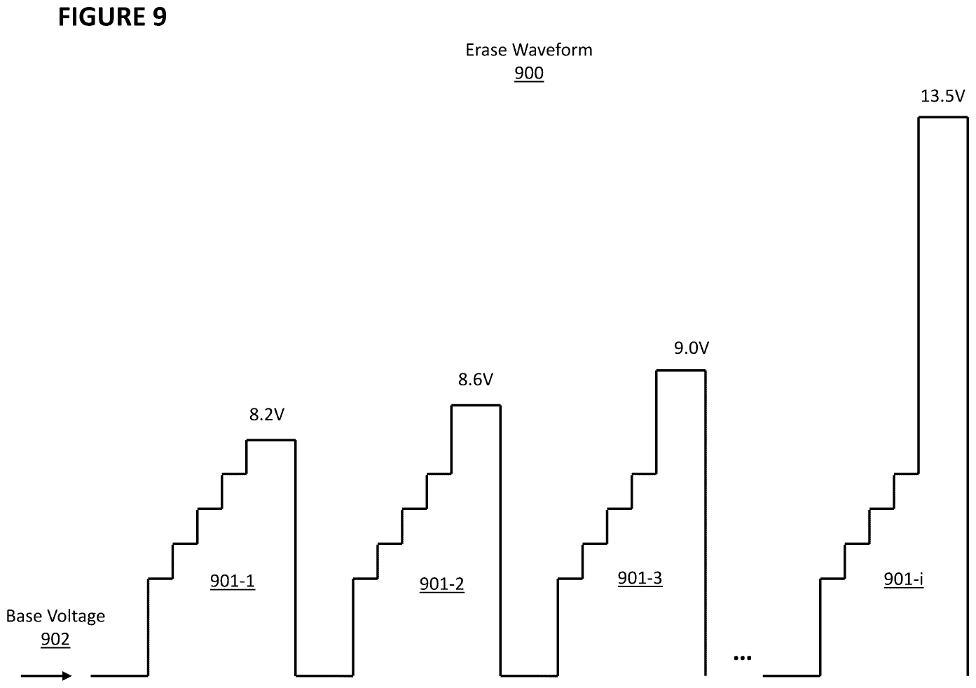

FIG. 9 depicts erase waveform 900. Erase waveform 900 is an example of a voltage waveform to be applied to word line terminal 22 of memory cell 110 in FIG. 1, erase gate terminal 30 or control gate terminal 28 of memory cell 210 in FIG. 2, erase gate terminal 30 of memory cell 310 in FIG. 3, and control gate terminal 22 or substrate 18 of memory cell 410 in FIG. 4 during an erase operation. Erase waveform 900 is generated by high voltage generation block 510 and algorithm controller 514.

Erase waveform 900 comprises sequences (pulses) 901-1, 901-2, 901-3, . . . , 901-i, where i is the number of sequences in erase waveform 900. Each of the sequences 901 comprises increasing voltages in a step pattern. All steps but the last step are identical among sequences 901. Within each sequence 901, the steps can be of uniform magnitude and duration, or they can be variable magnitude (e.g., the steps increase or decrease in size as the sequence progresses) or variable duration (e.g., the duration of each step increases or decreases in size as the sequence progresses). The last step in each sequence 901 is larger than the last step of the preceding sequence. In the example shown, i=16, and the last steps of sequences 901-1, 901-2, 901-3, . . . , 901-i are 8.2V, 8.6V, 9.0V, and 13.5V, respectively. After each of sequences 901, the voltage drops to base level 902, which can be ground or another voltage, for a short duration.

The value of i, initial voltage, the final voltage, the number of steps, and the duration of each step for each sequence 901 are parameters that can be provided or configured, during a programing process or a configuration process, to algorithm controller 514, which in turn generates erase waveform 900 in conjunction with high voltage generation block 510.

Sequences 901-1, 901-2, 901-3, . . . , 901-i reduce the amount of stress on the memory cell compared to a situation where a constant high erase voltage is applied to the cell from the outset.

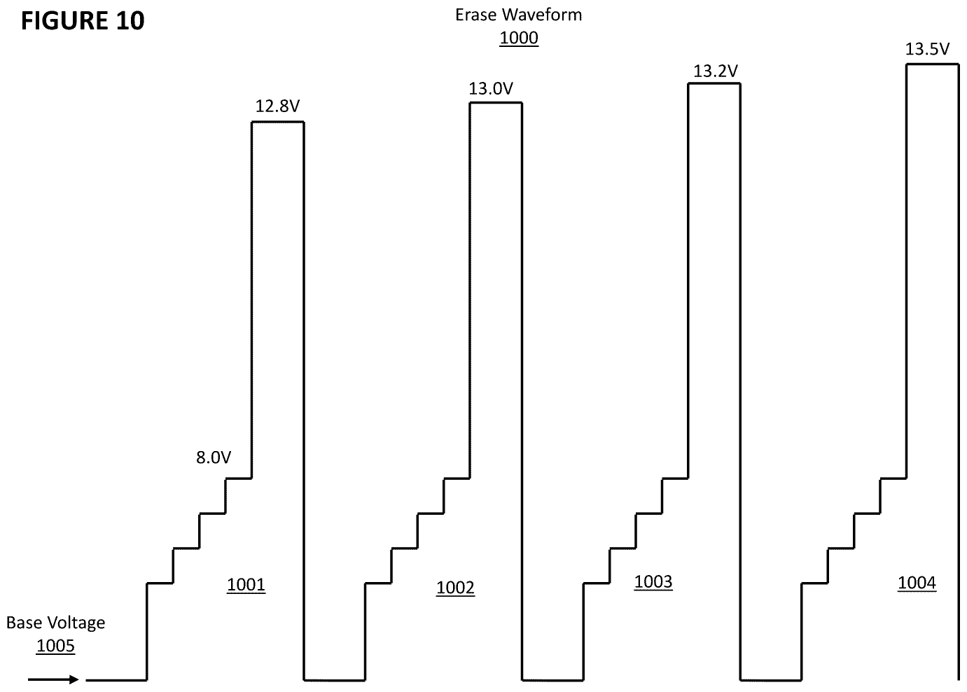

FIG. 10 shows erase waveform 1000, which is an example of erase waveform 900 in FIG. 9 with i=4. Erase waveform 1000 comprises sequences 1001, 1002, 1003, and 1004 with ending voltages of 12.8V, 13.0V, 13.2V, and 13.5V, respectively, and base voltage 1005.

Sequences 1001, 1002, 1003, and 1004 reduce the amount of stress on the memory cell compared to a situation where a constant high erase voltage is applied to the cell from the outset.

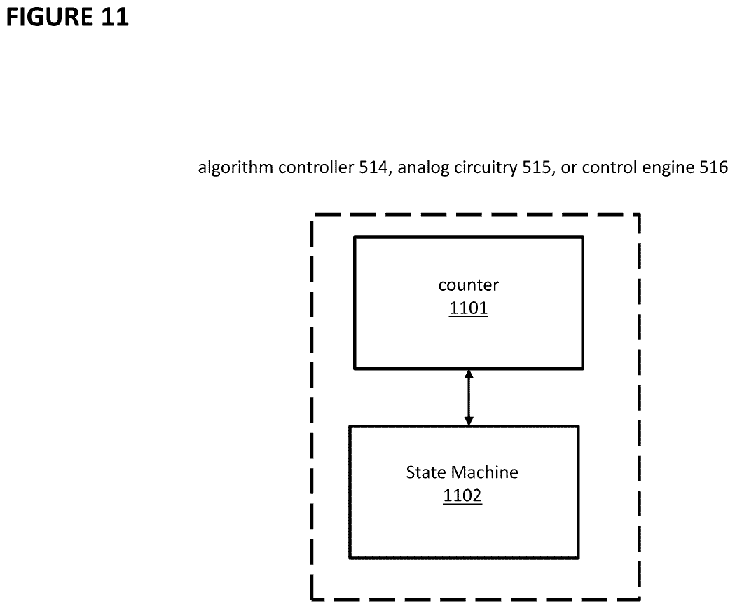

FIG. 11 depicts counter 1101 and state machine 1102, which can implement the erase waveforms 600, 800, 900, and 1000 in FIGS. 6, 8, 9, and 10, respectively. Counter 1101 and state machine 1102 are part of algorithm controller 514.

The improved system and method for erase operations for non-volatile memory cells disclosed herein increase the longevity of memory cells to enable them to perform a greater number of erase cycles before degradation occurs.

As used herein, the terms “over” and “on” both inclusively include “directly on” (no intermediate materials, elements or space disposed therebetween) and “indirectly on” (intermediate materials, elements or space disposed therebetween). Likewise, the term “adjacent” includes “directly adjacent” (no intermediate materials, elements or space disposed therebetween) and “indirectly adjacent” (intermediate materials, elements or space disposed there between), “mounted to” includes “directly mounted to” (no intermediate materials, elements or space disposed there between) and “indirectly mounted to” (intermediate materials, elements or spaced disposed there between), and “electrically coupled” includes “directly electrically coupled to” (no intermediate materials or elements there between that electrically connect the elements together) and “indirectly electrically coupled to” (intermediate materials or elements there between that electrically connect the elements together). For example, forming an element “over a substrate” can include forming the element directly on the substrate with no intermediate materials/elements therebetween, as well as forming the element indirectly on the substrate with one or more intermediate materials/elements there between.

What is claimed is:

1. A method for erasing a non-volatile memory cell, comprising:
performing a pre-erase sequence comprising applying voltages in a step pattern to a terminal of the non-volatile memory cell; and
performing an erase sequence comprising applying a plurality of pulses of voltages to the terminal.

2. The method of claim 1, wherein the plurality of pulses have a same voltage.

3. The method of claim 1, wherein the plurality of pulses have different voltages.

4. The method of claim 1, wherein the plurality of pulses each has a same duration.

5. The method of claim 1, wherein duration of the pulses in the plurality of pulses increases as the sequence progresses.

6. The method of claim 1, wherein duration of the pulses in the plurality of pulses decreases as the sequence progresses.

7. The method of claim 1, wherein the steps in the pre-erase sequence increase as the sequence progresses.

8. The method of claim 1, comprising:
performing a verify operation after the pre-erase sequence.

9. The method of claim 8, comprising:
performing a verify operation after each of the plurality of pulses.

10. The method of claim 1, comprising:
applying a base voltage to the terminal after the pre-erase sequence.

11. The method of claim 1, comprising:
applying a base voltage to the terminal after each of the plurality of pulses.

12. The method of claim 11, wherein the base voltage is ground or an intermediate voltage.

13. The method of claim 1, wherein the terminal is an erase gate terminal.

14. The method of claim 1, wherein the terminal is a control gate terminal.

15. The method of claim 1, wherein the terminal is a word line terminal.

16. The method of claim 1, wherein the terminal is a substrate.

17. A method for erasing a non-volatile memory cell, comprising:
performing a pre-erase sequence comprising applying to a terminal of the non-volatile memory cell a first plurality of sequences of voltages, each sequence of voltages in the first plurality of sequence of voltages comprising voltages in a step pattern; and
performing an erase sequence comprising applying to the terminal a second plurality of sequences of voltages, each sequence of voltages in the second plurality of sequences of voltages comprising voltages in a step pattern.

18. The method of claim 17, comprising:
performing a verify operation after each sequence of voltages in the first plurality of sequences of voltages.

19. The method of claim 18, comprising:
performing a verify operation after each sequence of voltages in the second plurality of sequences of voltages.

20. The method of claim 17, comprising:
applying a base voltage to the terminal after each sequence of voltages in the first plurality of sequences of voltages.

21. The method of claim 17, comprising:
applying a base voltage to the terminal after each sequence of voltages in the second plurality of sequences of voltages.

22. The method of claim 21, wherein the base voltage is ground.

23. The method of claim 17, wherein the terminal is an erase gate terminal.

24. The method of claim 17, wherein the terminal is a control gate terminal.

25. The method of claim 17, wherein the terminal is a word line terminal.

26. The method of claim 17, wherein the terminal is a substrate.

27. The method of claim 17, wherein the sequences of voltages in the second plurality of sequences of voltages each has a same duration.

28. The method of claim 17, wherein duration of the sequences of voltages in the second plurality of sequences of voltages increases as the erase sequence progresses.

29. The method of claim 17, wherein duration of the sequences of voltages in the second plurality of sequence of voltage decreases as the erase sequence progresses.

30. A method for erasing a non-volatile memory cell, comprising:
applying to a terminal of the non-volatile memory cell a plurality of sequences of voltages, each sequence of voltages in the plurality of sequence of voltages comprising voltages in a step pattern, wherein a last step of each sequence increases in magnitude compared to the preceding sequence.

31. The method of claim 30, comprising:
performing a verify operation after each sequence of voltages in the plurality of sequences of voltages.

32. The method of claim 30, comprising:
applying a base voltage to the terminal after each sequence of voltages in the plurality of sequences of voltages.

33. The method of claim 32, wherein the base voltage is ground or an intermediate voltage.

34. The method of claim 30, wherein the terminal is an erase gate terminal.

35. The method of claim 30, wherein the terminal is a control gate terminal.

36. The method of claim 30, wherein the terminal is a word line terminal.

37. The method of claim 30, wherein the terminal is a substrate.

38. The method of claim 30, wherein the sequences of voltages in the plurality of sequences of voltages each has a same duration.

39. The method of claim 30, wherein a duration of the sequences of voltages in the plurality of sequences of voltages increases from sequence to sequence.

40. The method of claim 30, wherein a duration of the sequences of voltages in the plurality of sequence of voltage decreases from sequence to sequence.

41. A controller for erasing a non-volatile memory cell, the controller configured to:
perform a pre-erase sequence comprising applying voltages in a step pattern to a terminal of the non-volatile memory cell; and
perform an erase sequence comprising applying a plurality pulses of increasing voltages to the terminal.

42. A controller for erasing a non-volatile memory cell, the controller configured to:
perform a pre-erase sequence comprising applying to a terminal of the non-volatile memory cell a first plurality of sequences of voltages, each sequence of voltages in the first plurality of sequence of voltages comprising voltages in a step pattern; and
perform an erase sequence comprising applying to the terminal a second plurality of sequences of voltages, each sequence of voltages in the second plurality of sequences of voltages comprising voltages in a step pattern.

43. A controller for erasing a non-volatile memory cell, the controller configured to:
apply to a terminal of the non-volatile memory cell a plurality of sequences of voltages, each sequence of voltages in the plurality of sequence of voltages comprising voltages in a step pattern, wherein a last step increases in magnitude with each sequence of voltages in the plurality of sequences of voltages.
